(19) United States
(12) Patent Application Publication
(10) Pub. No.: US 2023/0189606 A1
(43) Pub. Date: Jun. 15, 2023

(54) DISPLAY PANEL AND METHOD OF MANUFACTURING THE SAME

(71) Applicant: HKC CORPORATION LIMITED, SHENZHEN (CN)

(72) Inventors: KERONG WU, Shenzhen (CN); Haoxuan ZHENG, Shenzhen (CN)

(21) Appl. No.: 18/077,210

(22) Filed: Dec. 7, 2022

(30) Foreign Application Priority Data
Dec. 14, 2021 (CN) 202111523845.5

(51) Int. Cl. H10K 59/35; H10K 59/122; H10K 71/00

(52) U.S. Cl. CPC H01L 27/3218; H01L 27/3216; H01L 27/3213; H01L 27/3246; H01L 51/56; H01L 2227/323

(57) ABSTRACT

A display panel and a method of manufacturing a display panel are provided. The display panel includes an array substrate. The array substrate has a plurality of pixels. Each pixel includes an opening region and a non-opening region. An anode layer, a light emitting layer and a cathode layer are laminated in sequence in the opening region of the pixel. An auxiliary cathode layer and the cathode layer are laminated in sequence in the non-opening region of the pixel. The cathode layer in the opening region and the cathode layer in the non-opening region of the pixel are connected, and the auxiliary cathode layer is spaced apart from the anode layer. In this way, the cathode layer has high light transmission and good electrical conductivity, ensuring a better display effect.

### CROSS REFERENCE TO RELATED APPLICATIONS

The present application claims priority of Chinese Patent Application No. 202111523845.5, filed on Dec. 14, 2021, in China National Intellectual Property Administration, the entire contents of which are hereby incorporated by reference in their entireties.

### TECHNICAL FIELD

The present disclosure relates to the field of electroluminescence, and in particular to a display panel and a method of manufacturing a display panel.

### BACKGROUND

In the field of display technologies, an organic light emitting diode (OLED) display device has advantages of actively emitting light, having a high response speed, having a wide viewing angle, having high brightness, having high colour saturation, being thin, being bendable, having low cost, and so on. The OLED display devices are gradually replacing liquid crystal displays (LCDs) to be major displays in the flat panel display technology. According to a direction in which light is emitted, an OLED substrate may include a bottom-emitting OLED (the light is emitted downwardly relative to a substrate) and a top-emitting OLED (the light is emitted upwardly relative to the substrate) and so on. For the top-emitting OLED, the direction in which the light is emitted is on a cathode side, and therefore, configuration of the cathode may significantly affect display performance.

However, in the art, it may be difficult to enable the cathode to have high light transmission, and at the same time, to meet requirements of proper electrical conductivity. For example, in order to achieve the high light transmission, thickness of the cathode may be thin. However, resistance of the thin cathode may be large, leading to an increased voltage and increased power consumption. Further, the voltage may be unevenly distributed on various regions of the cathode, causing uneven brightness.

### SUMMARY OF THE DISCLOSURE

According to a first aspect, a display panel is provided and includes an array substrate. The array substrate has a plurality of pixels, each of the plurality of pixels includes an opening region and a non-opening region. An anode layer, a light emitting layer and a portion of a cathode layer are laminated in sequence in the opening region of the pixel. An auxiliary cathode layer and another portion of the cathode layer are laminated in sequence in the non-opening region of the pixel. The portion of the cathode layer in the opening region and the another portion of the cathode layer in the non-opening region of the pixel are connected, and the auxiliary cathode layer is spaced apart from the anode layer.

According to a second aspect, an electronic device is provided and includes: a circuit substrate and the display panel of the first aspect. The display panel is arranged on and electrically connected to the circuit substrate. The circuit substrate is configured to supply power and a drive voltage for the display panel.

According to a third aspect, a method of manufacturing a display panel is provided and includes: providing an array substrate, forming an anode layer and an auxiliary cathode layer on the array substrate, wherein the anode layer and the auxiliary cathode layer are spaced apart from each other; forming a light emitting layer on the anode layer; and forming a cathode layer on the light emitting layer and the auxiliary cathode layer.

According to the present disclosure, the display panel is arranged with an auxiliary cathode layer and a cathode layer laminated in sequence in the non-opening region of the pixels. The cathode layer in the opening region of the pixels is connected to the cathode layer in the non-opening region of the pixels. The auxiliary cathode layer is spaced apart from the anode layer. In this way, electrical conductivity of the cathode layer may be effectively increased due to connection with the auxiliary cathode layer to reduce an overall impedance of the cathode layer, and the thickness of the cathode layer does not need to be increased to increase the electrical conductivity of the display panel. Therefore, the cathode layer has high light transmission and good electrical conductivity, ensuring a better display effect.

### BRIEF DESCRIPTION OF THE DRAWINGS

In order to illustrate more clearly technical solutions in embodiments of the present disclosure, the accompanying drawings for the description of the embodiments will be briefly described in the following. Apparently, the following are only some of the embodiments of the present disclosure, and other drawings can be obtained based on the following drawings without creative work by any ordinary skilled person in the art.

FIG. 1 is a structural schematic view of a display panel according to an embodiment of the present disclosure.

FIG. 2 is a top view of a cross section of a display panel according to an embodiment of the present disclosure.

FIG. 3 is a top view of a cross section of a display panel according to another embodiment of the present disclosure.

FIG. 4a is a flow chart of a method of manufacturing a display panel according to a first embodiment of the present disclosure.

FIG. 4b is a structural schematic view of a display panel corresponding to the operation S21 in FIG. 4a.

FIG. 4c is a structural schematic view of a display panel corresponding to the operation S22 in FIG. 4a.

FIG. 4d is a structural schematic view of a display panel corresponding to the operation S22 in FIG. 4a.

FIG. 4e is a structural schematic view of a display panel corresponding to the operation S23 in FIG. 4a.

FIG. 4f is a structural schematic view of a display panel after the operation S23 in FIG. 4a.

FIG. 5 is a flow chart of a method of manufacturing a display panel according to a second embodiment of the present disclosure.

FIG. 6 is a structural schematic view of an OLED display according to an embodiment of the present disclosure.

### DETAILED DESCRIPTION

Technical solutions in the embodiments of the present disclosure will be clearly and completely described below by referring to the accompanying drawings in the embodiments of the present disclosure. Apparently, the embodiments described are only a part of but not all of the embodiments of the present disclosure. Based on the embodiments in the present disclosure, all other embodiments obtained without creative work by any ordinary skilled person in the art shall fall within the scope of the present disclosure.

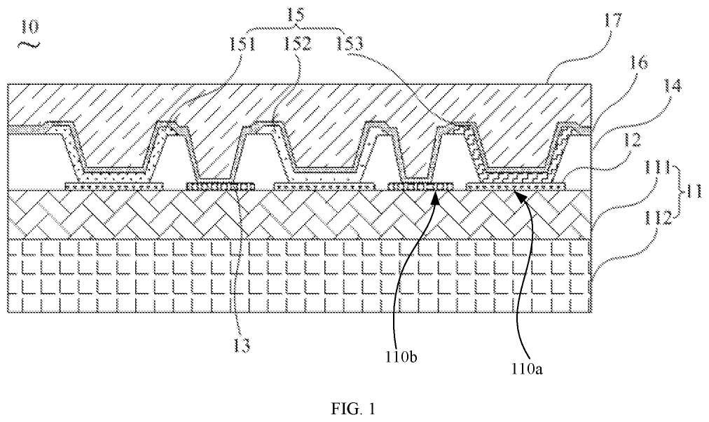

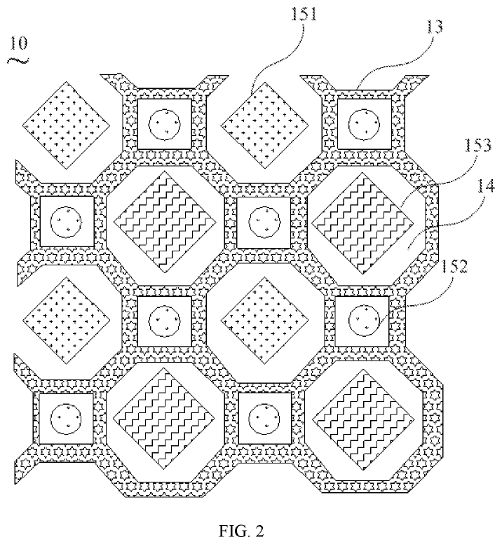

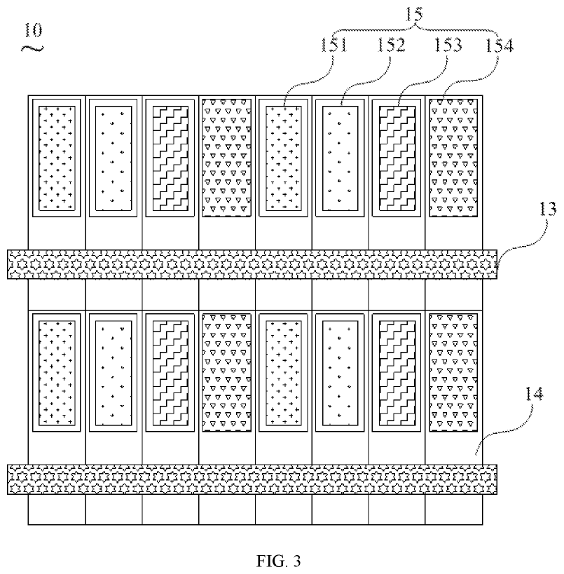

As shown in FIGS. 1-3, FIG. 1 is a structural schematic view of a display panel according to an embodiment of the present disclosure, FIG. 2 is a top view of a cross section of an implementation of the display panel shown in FIG. 1, and FIG. 3 is a top view of a cross section of another implementation of the display panel shown in FIG. 1. In the present embodiment, a display panel 10 may include: an array substrate 11, an anode layer 12, an auxiliary cathode layer 13, a light emitting layer 15 and a cathode layer 16.

In detail, the array substrate 11 may have a plurality of pixels. Each of the plurality of pixels may include an opening region 110a and a non-opening region 110b. The anode layer 12, the light emitting layer 15 and the cathode layer 16 are arranged in sequence in the opening region 110a of the pixel.

Further, the auxiliary cathode layer 13 and the cathode layer 16 may be arranged in sequence in the non-opening region 110b of the pixel. The cathode layer 16 in the opening region 110a and the cathode layer 16 in the non-opening region 110b of the pixel are connected. Therefore, the cathode layer 16 may be connected to the auxiliary cathode layer 13, and the auxiliary cathode layer 13 may be spaced apart from the anode layer 12.

To be noted that, the opening region 110a of the pixel may refer to a light transmission region that light behind a wiring portion and a transistor portion (usually hidden by a black matrix) of each pixel can pass through. The non-opening region 110b may refer to a partial region that the light behind the wiring portion and the transistor portion (usually hidden by the black matrix) of each pixel cannot pass through, and therefore, the non-opening region 110b may be the non-transmitted region.

In the above embodiment, the cathode layer 16 may be connected to the auxiliary cathode layer 13, and the auxiliary cathode layer 13 may be spaced from the anode layer 12. The electrical conductivity of the cathode layer 16 may be effectively increased, and an overall impedance of the cathode layer 16 may be reduced. Therefore, thickness of the cathode layer 16 does not need to be increased to achieve the electrical conductivity of the display panel 10. Therefore, the cathode layer 16 may have high light transmission and better electrical conductivity, ensuring a better display effect.

In an embodiment, the array substrate 11 may specifically include a thin film transistor (TFT) layer 111 and a substrate 112, such as a glass substrate 112 or any other substrate 112 made from appropriate material. The array substrate 11 may specifically be configured to drive each pixel in the display panel 10. Therefore, a corresponding anode layer 12 may specifically be arranged on a side of the array substrate 11 to be able to receive a signal input correspondingly sent by the array substrate 11.

In an embodiment, the pixel may further include a plurality of sub-pixels. Specifically, the sub-pixels are a R sub-pixel, a G sub-pixel and a B sub-pixel. Each of the sub-pixels may correspond to one opening region 110a and one non-opening region 110b. The auxiliary cathode layer 13 may be arranged in the non-opening region 110b corresponding to each of the sub-pixels. Adjacent auxiliary cathode layers 13 may be connected with each other to form an auxiliary cathode ring, surrounding each sub-pixel. A plurality of auxiliary cathode rings may form a grid of auxiliary cathode layer 13.

In an embodiment, the anode layer 12 may specifically include a plurality of anodes. The plurality of anodes may be spaced apart from each other and may be arranged on the array substrate 11. The light emitting layer 15 may further include a plurality of light emitting subunits, and the plurality of light emitting subunits are in one-to-one correspondence to the plurality of sub-pixels. Each of the plurality of light emitting subunits may be arranged on one anode.

It shall be understood that, as shown in FIG. 2, for illustrative purposes, FIG. 2 may be interpreted as a top view of the display panel 10, which is not entirely arranged with the cathode layer 16. The sub-pixels may arranged as a pentile arrangement (an arrangement of three-color sub-pixels, each of an area occupied by the red sub-pixel and an area occupied by the blue sub- pixel is two times of an area occupied by the green sub-pixel) or a diamond arrangement. For illustrative purposes, the light emitting layer 15 may include an R-emitting subunit 151 corresponding to the R sub-pixel, a G-emitting subunit 152 corresponding to the G sub-pixel and a B-emitting subunit 153 corresponding to the B sub-pixel. One sub-pixel and one light emitting unit corresponding to the sub-pixel may be arranged in one grid of the auxiliary cathode layer 13. In this way, the impedance of the cathode layer 16 connected to the auxiliary cathode layer 13 may further be effectively reduced, and homogeneity of the display of the cathode layer 16 may be improved.

Further, the sub-pixels may be the R sub-pixel, the G sub-pixel, the B sub-pixel and a W sub-pixel. Each sub-pixel may correspond to one opening region 110a and one non-opening region 110b. The R sub-pixel, the G sub-pixel, the B sub-pixel and the W sub-pixel may be arranged next to each other in sequence and arranged in a plurality of rows, forming an array. The auxiliary cathode layer 13 may further be arranged in the non-opening region 110b between sub-pixels of two adjacent rows. Alternatively, a sub-pixel at an edge row may have a non-opening region 110b at an edge, and the auxiliary cathode layer 13 may be arranged in the non-opening region 110b at the edge.

It shall be understood that, as shown in FIG. 3, for illustrative purposes, FIG. 3 may be interpreted as the top view of the display panel 10, which is not entirely arranged with the cathode layer 16. Similarly, the light emitting layer 15 may further include a plurality of R-emitting subunits 151, G-emitting subunits 152, B-emitting subunits 153 and W-emitting subunits 154. The plurality of R-emitting subunits 151, G-emitting subunits 152, B-emitting subunits 153 and W-emitting subunits 154 may be arranged in an array. Subpixels in two adjacent rows or in two adjacent columns may be spaced apart from each other by the auxiliary cathode layer 13. Alternatively, subpixels in an edge row may be arranged in the non-opening region 110b at the edge.

In an embodiment, the display panel 10 may further include a pixel defining layer 14, arranged on the array substrate 11. The pixel definition layer 14 may define a first through hole 342, exposing the anode layer 12. The anode layer 12 may be arranged at a bottom of the first through hole 342. The light emitting layer 15 may further be arranged on the anode layer 12. That is, the light emitting layer 15 may be arranged on the bottom of the first through hole 342 and a side wall of the first through hole 342. The cathode layer 16 may further be arranged on the light emitting layer 15.

Further, in an embodiment, the pixel defining layer may define a second through hole 343, exposing at least part of the auxiliary cathode layer 13. The auxiliary cathode layer 13 may be arranged at a bottom of the second through hole 343. The cathode layer 16 may further be arranged on the auxiliary cathode layer 13. That is, the cathode layer 16 may be arranged on the bottom of the second through hole 343 and on a side wall of the second through hole 343. In this way, the cathode layer 16 may be connected to the auxiliary cathode layer 13.

Further, in an embodiment, the anode layer 12 may include a plurality of anodes. The plurality of anodes may be spaced apart from each other and may be arranged on the array substrate 11. The light emitting layer 15 may further include a plurality of light emitting subunits, and the plurality of light emitting subunits may be in one-to-one correspondence to the plurality of subpixels. Each of the plurality of light emitting subunits may be arranged on one anode and the side wall of the first through hole 342 corresponding to the anode.

In some embodiments, the pixel defining layer may define the second through hole 343, exposing entirety of the auxiliary cathode layer 13, and the auxiliary cathode layer 13 may be arranged at the bottom of the second through hole 343. The cathode layer 16 may further be arranged on the auxiliary cathode layer 13 and the side wall of the second through hole 343.

It shall be understood that, the pixel defining layer may define the second through hole 343 corresponding to the auxiliary cathode layer 13. In this way, the anode layer 12 which is arranged apart from the auxiliary cathode layer 13, i.e., every two adjacent light emitting subunits arranged on the plurality of anodes, may be separated effectively. Interference of light mixing of adjacent subpixels may be effectively blocked by defining the recess, ensuring the display panel 10 to have a better display effect.

In an embodiment, a conductive via 343a may be defined in the pixel defining layer and correspond to the auxiliary cathode layer 13, or a conductive metal post may be arranged on the pixel defining layer and correspond to the auxiliary cathode layer 13. Further, the cathode layer 16 may be received in the conductive via 343a or connected to the conductive metal post. For example, the conductive metal post may be a conductive copper post or a conductive aluminum post. The cathode layer 16 may be connected to the auxiliary cathode layer 13 through the conductive via 343a or the conductive metal post.

In an embodiment, the auxiliary cathode layer 13 and the anode layer 12 may be arranged on a same layer and may be spaced apart from each other. In this way, when the cathode layer 16 is connected to the auxiliary cathode layer 13, the impedance of the cathode layer 16 may be reduced effectively. In other embodiments, the auxiliary cathode layer 13 may be arranged between the anode layer 12 and a side of the pixel defining layer away from the array substrate 11. The present disclosure does not limit the location of the auxiliary cathode layer 13, as long as the above functions can be achieved.

In an embodiment, the cathode layer 16 may specifically be arranged on the side of the pixel defining layer 14 away from the array substrate 11. The entire the cathode layer 16 may cover the auxiliary cathode layer 13, the pixel defining layer 14, the side wall of the first through hole 342, the side wall of the second through hole 343, and the light emitting layer 15, such that the cathode layer 16 may be connected to the auxiliary cathode layer 13 correspondingly.

In an embodiment, material of the auxiliary cathode layer 13 may be the same as that of the anode layer 12, such that the anode layer 12 and the auxiliary cathode layer 13 may be made simultaneously by performing a same preparation process, an overall preparation cost of the display panel 10 may be reduced as much as possible.

In an embodiment, the display panel 10 may further include an encapsulation layer 17. The encapsulation layer 17 may be arranged on the cathode layer 16 to achieve encapsulation protection of the cathode layer 16 and to insulate the cathode layer 16 from water and oxygen.

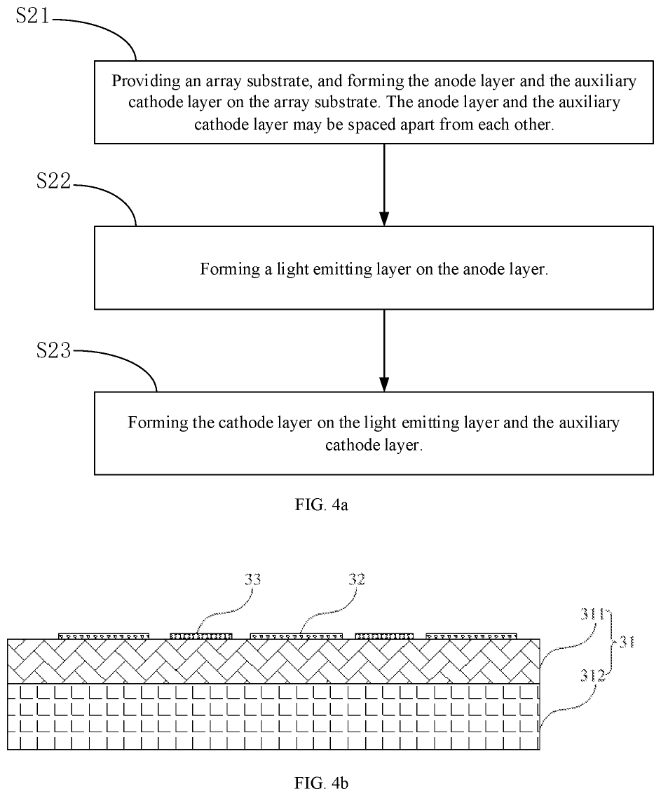

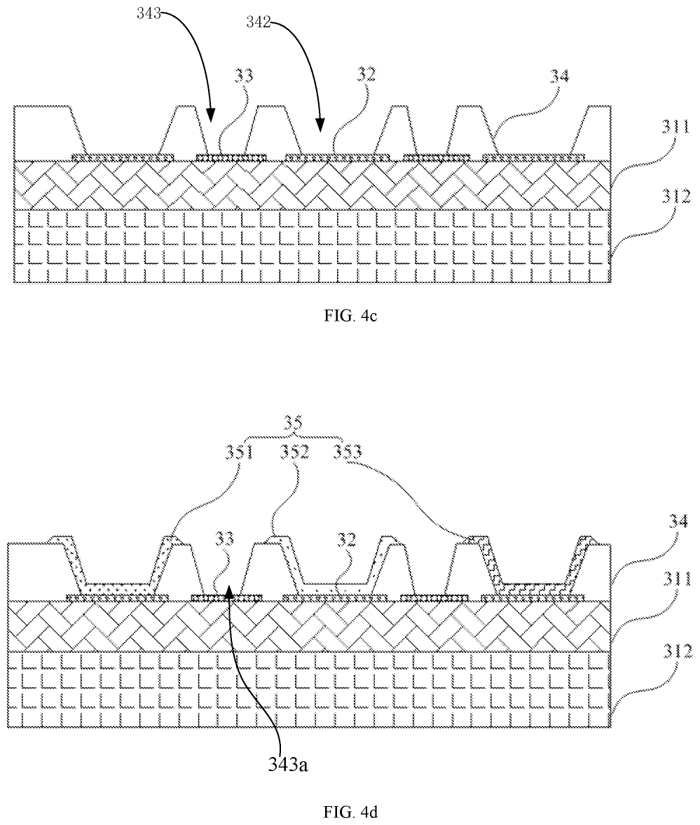

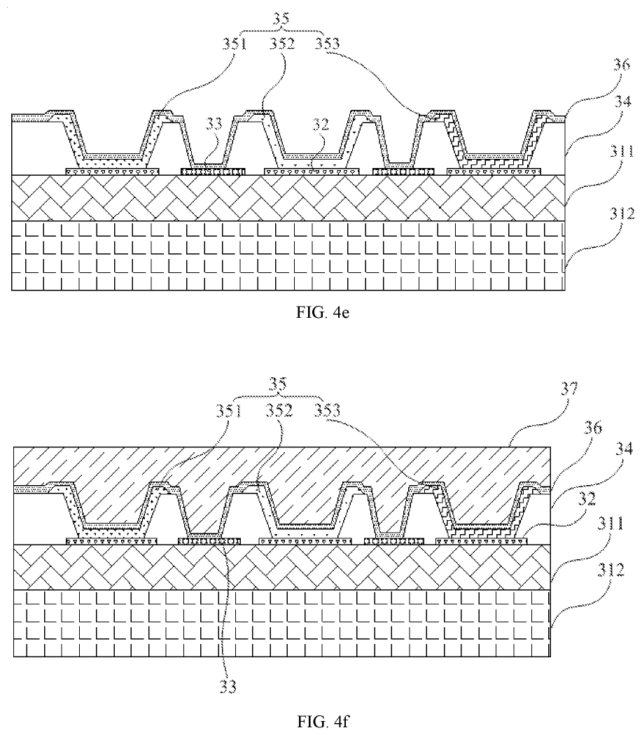

The present disclosure further provides a method of manufacturing a display panel, as shown in FIGS. 4a-4f. FIG. 4a is a flow chart of a method of manufacturing a display panel according to a first embodiment of the present disclosure. FIG. 4b-FIG. 4f are structural schematic views of display panels corresponding to the operation S21-S23 in FIG. 4a. The present embodiment may include following operations.

In an operation S21, an array substrate may be provided, and the anode layer and the auxiliary cathode layer may be formed on the array substrate and may be spaced apart from each other.

In detail, as shown in FIG. 4b, after the array substrate 31 is provided, the anode layer 32 and the auxiliary cathode layer 33 may be formed in sequence on the array substrate 31, and the anode layer 32 and the auxiliary cathode layer 33 may be spaced apart from each other. For example, designed wiring patterns of the anode layer 32 and the auxiliary cathode layer 33 may be simultaneously formed by performing film formation, exposure development, etching, and so on, such that the anode layer 32 and the auxiliary cathode layer 33 may be spaced apart from each other without interconnection. By manufacturing the anode layer 32 and the auxiliary cathode layer 33 in the same process, the overall production cost of the display panel may be reduced as much as possible.

In an embodiment, the array substrate 31 may specifically include a thin film transistor layer 311 and a substrate 312. For example, the array substrate 31 may be a glass substrate 312 or any other substrate 312 made of appropriate material. The array substrate 31 may specifically be configured to drive each pixel in the display panel. Therefore, the corresponding anode layer 32 may specifically be arranged on a side of the array substrate 31 to be able to receive the signal input correspondingly sent by the array substrate 31.

The array substrate 31 may have a plurality of pixels. Each of the plurality of pixels may include an opening region and a non-opening region. The anode layer 32 may be arranged in the opening region of the pixel, and the auxiliary cathode layer 33 may be arranged in the non- opening region of the pixel.

In an operation S22, a light emitting layer may be formed on the anode layer.

Further, as shown in FIGS. 4c and 4d, the light emitting layer 35 may be deposited on the anode layer 32. For example, a FMM mask (mask plate) vapour deposition process may be performed to form the light emitting layer 35 on the anode layer 32.

In an operation S23, a cathode layer may be formed on the light emitting layer and the auxiliary cathode layer.

Further, as shown in FIG. 4e, an open mask process may be performed to produce the cathode layer 36 on the light emitting layer 35 and the auxiliary cathode layer 33 simultaneously, and to allow the cathode layer 36 to be connected to the auxiliary cathode layer 33.

Further, in an embodiment, as shown in FIG. 4f, after the operation S23, the method may further include: forming an encapsulation layer 37 on the cathode layer 36 to protect the cathode layer 36 and insulate the cathode layer 36 from water and oxygen.

As shown in FIG. 5, FIG. 5 is a flow chart of a method of manufacturing a display panel according to a second embodiment of the present disclosure. The method of manufacturing the display panel of the present embodiment is a flow chart of a detailed embodiment of the method of manufacturing the display panel of FIG. 4a. In the present embodiment, the method may include following operations.

In an operation S41, an array substrate may be provided, the anode layer and the auxiliary cathode layer are formed on the array substrate and are spaced apart from each other.

The operations S41 and S42 may be identical to the operations S21 and S22 in FIG. 4a, and may refer to description about S21 and S22 for details, which will not be repeated here.

In an operation S42, a pixel defining layer may be formed on the array substrate, a first through hole 342 may be defined in the pixel defining layer to expose the anode layer and to directly face the anode layer, and a second through hole 343 may be defined in the pixel defining layer to expose at least part of the auxiliary cathode layer and to directly face the auxiliary cathode layer.

In detail, as shown in FIG. 4c, the pixel definition layer 34 may be formed on the array substrate 31. The first through hole 342 may be defined in the pixel defining layer to directly face the anode layer 32 and to expose the anode layer 32, and the second through hole 343 may be defined in the pixel defining layer to directly face the auxiliary cathode layer 33 and to expose at least part of the auxiliary cathode layer 33. In some embodiments, the second through hole 343 may expose the entire auxiliary cathode layer 33.

In an operation S43, a light emitting layer may be formed on the anode layer.

Further, as shown in FIG. 4d, the FMM mask (mask plate) vapour deposition process may be performed to form the light emitting layer 35 on the anode layer 32.

In an embodiment, the pixel may further include a plurality of sub-pixels. Specifically, the sub-pixels are a R sub-pixel, a G sub-pixel and a B sub-pixel. Each of the sub-pixels may correspond to one opening region and one non-opening region. The auxiliary cathode layer 33 may be formed in the non-opening region corresponding to each of the sub-pixels. Adjacent auxiliary cathode layers 33 may be connected with each other to form an auxiliary cathode ring, surrounding each sub-pixel. A plurality of auxiliary cathode rings may form a grid of auxiliary cathode layer 33.

In an embodiment, the anode layer 32 may specifically include a plurality of anodes. The plurality of anodes may be spaced apart from each other and may be formed on the array substrate 31. The light emitting layer 35 may further include a plurality of light emitting subunits, and the plurality of light emitting subunits are in one-to-one correspondence to the plurality of sub-pixels. Each of the plurality of light emitting subunits may be arranged on one anode.

It shall be understood that, as shown in FIG. 2, for illustrative purposes, FIG. 2 may be interpreted as a top view of the display panel 10, which is not entirely arranged with the cathode layer 36. The sub-pixels may be arranged as the pentile arrangement (the arrangement of three- color sub-pixels, each of the area occupied by the red sub-pixel and the area occupied by the blue sub-pixel is two times of the area occupied by the green sub-pixel) or the diamond arrangement. For illustrative purposes, the light emitting layer 35 may include an R-emitting subunit 351 corresponding to the R sub-pixel, a G-emitting subunit 352 corresponding to the G sub-pixel and a B-emitting subunit 353 corresponding to the B sub-pixel. One sub-pixel and one light emitting unit corresponding to the sub-pixel may be arranged in one grid of the auxiliary cathode layer 33. In this way, the impedance of the cathode layer 36 connected to the auxiliary cathode layer 33 may further be effectively reduced, and homogeneity of the display of the cathode layer 36 may be improved.

Further, the sub-pixels may be the R sub-pixel, the G sub-pixel, the B sub-pixel and a W sub-pixel. Each sub-pixel may correspond to one opening region and one non-opening region. The R sub-pixel, the G sub-pixel, the B sub-pixel and the W sub-pixel may be arranged next to each other in sequence and arranged in a plurality of rows, forming an array. The auxiliary cathode layer 33 may further be arranged in the non-opening region between sub-pixels of two adjacent rows. Alternatively, a sub-pixel at an edge row may have a non-opening region at an edge, and the auxiliary cathode layer 33 may be arranged in the non-opening region at the edge.

It shall be understood that, as shown in FIG. 3, for illustrative purposes, FIG. 3 may be interpreted as the top view of the display panel 10, which is not entirely arranged with the cathode layer 36. Similarly, the light emitting layer 35 may further include a plurality of R-emitting subunits 351, G-emitting subunits 352, B-emitting subunits 353 and W-emitting subunits 354. The plurality of R-emitting subunits 351, G-emitting subunits 352, B-emitting subunits 353 and W-emitting subunits 354 may be arranged in an array. Subpixels in two adjacent rows or in two adjacent columns may be spaced apart from each other by the auxiliary cathode layer 33. Alternatively, subpixels in an edge row may be arranged in the non-opening region at the edge.

In an operation S44, the cathode layer may be arranged on the light emitting layer, the pixel defining layer, the side wall of the first through hole 342, the side wall of the second through hole 343 and the auxiliary cathode layer.

Further, as shown in FIG. 4e, the open mask process may be performed to form the cathode layer 36 on a side of the pixel defining layer 34 away from the array substrate 31, allowing the cathode layer 36 to cover the auxiliary cathode layer 33, the pixel defining layer 34, the side wall of the first through hole 342, the side wall of the second through hole 343 and the light emitting layer 35, such that the cathode layer 36 may be connected to the auxiliary cathode layer 33.

In other embodiments, a conductive via 343a may be defined in the pixel defining layer and correspond to the auxiliary cathode layer 33, or a conductive metal post may be arranged on the pixel defining layer and correspond to the auxiliary cathode layer 33. Further, the cathode layer 36 may be received in the conductive via 343a or connected to the conductive metal post. For example, the conductive metal post may be a conductive copper post or a conductive aluminum post. The cathode layer 36 may be connected to the auxiliary cathode layer 33 through the conductive via 343a or the conductive metal post.

Further, in an embodiment, the operation S43 may specifically further include: depositing a hole injection layer, a hole transport layer, a first hole blocking layer and an electron blocking layer in sequence on the anode layer 32 and the side wall of the first through hole 342 corresponding to the anode layer 32, enabling the light emitting layer 35 to be arranged on the electron blocking layer.

Further, in an embodiment, the operation S44 may further include: depositing in sequence a second hole blocking layer, an electron transport layer, and an electron injection layer on the auxiliary cathode layer 33, the pixel defining layer 34, the side wall of the first through hole 342, the side wall of the second through hole 343, and the light emitting layer 35, enabling the cathode layer 36 to be arranged on the electron injection layer.

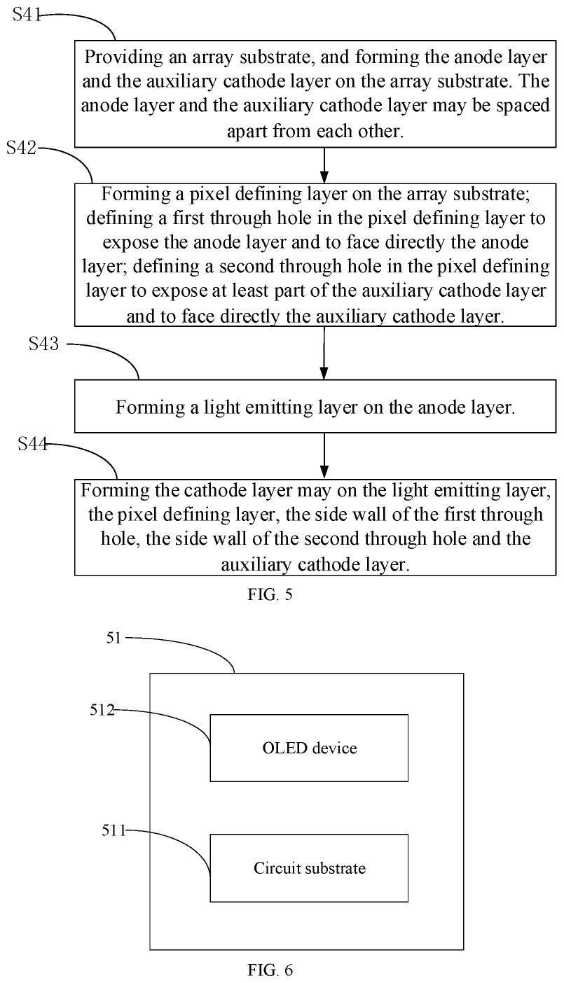

The present disclosure further provides an electronic device, as shown in FIG. 6, FIG. 6 is a structural schematic view of an OLED display according to an embodiment of the present disclosure. The OLED display 51 may include a circuit substrate 511 and a display panel 512 arranged on the circuit substrate 511, and the circuit substrate 511 and the display panel 512 may be electrically connected with each other.

To be noted that, the circuit substrate 511 may specifically be configured to supply power and a drive voltage for the display panel 512, and provide circuit logic lines for electrical connection with external devices or components. The display panel 512 described in the present embodiment may be the display panel 10 described in any of the above embodiments, which will not be repeated here.

According to the present disclosure, the display panel is arranged with an auxiliary cathode layer and a cathode layer laminated in sequence in the non-opening region of the pixels. The cathode layer in the opening region of the pixels is connected to the cathode layer in the non-opening region of the pixels. The auxiliary cathode layer is spaced apart from the anode layer. In this way, electrical conductivity of the cathode layer may be effectively increased due to connection with the auxiliary cathode layer to reduce an overall impedance of the cathode layer, and the thickness of the cathode layer does not need to be increased to increase the electrical conductivity of the display panel. Therefore, the cathode layer has high light transmission and good electrical conductivity, ensuring a better display effect.

The above description shows only embodiments of the present disclosure and does not limit the scope of the present disclosure. Any equivalent structure or equivalent process transformation performed based on the specification and accompanying drawings, applied directly or indirectly in other related fields, shall be equally covered by the scope of the present disclosure.

What is claimed is:

1. A display panel, comprising an array substrate, the array substrate having a plurality of pixels, each of the plurality of pixels comprising an opening region and a non-opening region, an anode layer, a light emitting layer and a portion of a cathode layer being laminated in sequence in the opening region of the pixel, wherein,
an auxiliary cathode layer and another portion of the cathode layer are laminated in sequence in the non-opening region of the pixel, the portion of the cathode layer in the opening region and the another portion of the cathode layer in the non-opening region of the pixel are connected, and the auxiliary cathode layer is spaced apart from the anode layer.

2. The display panel according to claim 1, wherein,
each of the plurality of pixels comprises a plurality of sub-pixels, the sub-pixels are a R sub- pixel, a G sub-pixel and a B sub-pixel;
each of the plurality of sub-pixels corresponds to one opening region and one non-opening region;
the auxiliary cathode layer is arranged in the non-opening region corresponding to each of the plurality of sub-pixels;
any adjacent auxiliary cathode layers are connected with each other to form an auxiliary cathode ring, surrounding each of the plurality of sub-pixels; and
a plurality of auxiliary cathode rings cooperatively form a grid of the auxiliary cathode layer.

3. The display panel according to claim 1, wherein,
each of the plurality of pixels comprises a plurality of sub-pixels, the sub-pixels are a R sub- pixel, a G sub-pixel, a B sub-pixel and a W sub-pixel;
each of the plurality of sub-pixels corresponds to one opening region and one non-opening region;
the R sub-pixel, the G sub-pixel, the B sub-pixel and the W sub-pixel are arranged adjacent to each other in sequence and are arranged in a plurality of rows forming an array;
the auxiliary cathode layer is arranged in a non-opening region between the sub-pixels in two adjacent rows; or
the sub-pixels at an edge row have a non-opening region at an edge, and the auxiliary cathode layer is arranged in the non-opening region at the edge.

4. The display panel according to claim 1, further comprising a pixel defining layer, wherein,
the pixel defining layer is arranged on the array substrate;
the pixel definition layer defines a first through hole, exposing the anode layer, wherein the anode layer is arranged at a bottom of the first through hole;
the light emitting layer is arranged on the anode layer and a side wall of the first through hole; and
the cathode layer is arranged on the light emitting layer.

5. The display panel according to claim 4, wherein,
the pixel defining layer defines a second through hole, exposing at least part of the auxiliary cathode layer;
the auxiliary cathode layer is arranged at a bottom of the second through hole; and
the cathode layer is arranged on the auxiliary cathode layer and on a side wall of the second through hole.

6. The display panel according to claim 4, wherein,
a conductive via is defined in the pixel defining layer and corresponds to the auxiliary cathode layer, or a conductive metal post is arranged on the pixel defining layer and corresponds to the auxiliary cathode layer; and
the cathode layer is connected to the auxiliary cathode layer through the conductive via or the conductive metal post.

7. The display panel according to claim 1, wherein the auxiliary cathode layer and the anode layer are arranged on a same layer and are spaced apart from each other.

8. The display panel according to claim 1, wherein material of the auxiliary cathode layer is the same as material of the anode layer.

9. An electronic device, comprising: a circuit substrate and a display panel arranged on and electrically connected to the circuit substrate, wherein the circuit substrate is configured to supply power and a drive voltage for the display panel, and the display panel comprises:
an array substrate, the array substrate having a plurality of pixels, each of the plurality of pixels comprising an opening region and a non-opening region, an anode layer, a light emitting layer and a portion of a cathode layer being laminated in sequence in the opening region of the pixel, wherein,
an auxiliary cathode layer and another portion of the cathode layer are laminated in sequence in the non-opening region of the pixel, the portion of the cathode layer in the opening region and the another portion of the cathode layer in the non-opening region of the pixel are connected, and the auxiliary cathode layer is spaced apart from the anode layer.

10. The electronic device according to claim 9, wherein,
each of the plurality of pixels comprises a plurality of sub-pixels, the sub-pixels are a R sub-pixel, a G sub-pixel and a B sub-pixel;
each of the plurality of sub-pixels corresponds to one opening region and one non-opening region;
the auxiliary cathode layer is arranged in the non-opening region corresponding to each of the plurality of sub-pixels;
any adjacent auxiliary cathode layers are connected with each other to form an auxiliary cathode ring, surrounding each of the plurality of sub-pixels; and
a plurality of auxiliary cathode rings cooperatively form a grid of the auxiliary cathode layer.

11. The electronic device according to claim 9, wherein,
each of the plurality of pixels comprises a plurality of sub-pixels, the sub-pixels are a R sub-pixel, a G sub-pixel, a B sub-pixel and a W sub-pixel;
each of the plurality of sub-pixels corresponds to one opening region and one non-opening region;
the R sub-pixel, the G sub-pixel, the B sub-pixel and the W sub-pixel are arranged adjacent to each other in sequence and are arranged in a plurality of rows forming an array;
the auxiliary cathode layer is arranged in a non-opening region between the sub-pixels in two adjacent rows; or
the sub-pixels at an edge row have a non-opening region at an edge, and the auxiliary cathode layer is arranged in the non-opening region at the edge.

12. The electronic device according to claim 9, wherein the display panel further comprises a pixel defining layer, wherein,
the pixel defining layer is arranged on the array substrate;
the pixel definition layer defines a first through hole, exposing the anode layer, wherein the anode layer is arranged at a bottom of the first through hole;
the light emitting layer is arranged on the anode layer and a side wall of the first through hole; and
the cathode layer is arranged on the light emitting layer.

13. The electronic device according to claim 12, wherein,
the pixel defining layer defines a second through hole, exposing at least part of the auxiliary cathode layer;
the auxiliary cathode layer is arranged at a bottom of the second through hole; and
the cathode layer is arranged on the auxiliary cathode layer and on a side wall of the second through hole.

14. The electronic device according to claim 12, wherein,
a conductive via is defined in the pixel defining layer and corresponds to the auxiliary cathode layer, or a conductive metal post is arranged on the pixel defining layer and corresponds to the auxiliary cathode layer; and
the cathode layer is connected to the auxiliary cathode layer through the conductive via or the conductive metal post.

15. The electronic device according to claim 9, wherein the auxiliary cathode layer and the anode layer are arranged on a same layer and are spaced apart from each other.

16. The electronic device according to claim 9, wherein material of the auxiliary cathode layer is the same as material of the anode layer.

17. A method of manufacturing a display panel, comprising:
providing an array substrate, forming an anode layer and an auxiliary cathode layer on the array substrate, wherein the anode layer and the auxiliary cathode layer are spaced apart from each other;
forming a light emitting layer on the anode layer; and
forming a cathode layer on the light emitting layer and the auxiliary cathode layer.

18. The method according to claim 17, wherein after the providing an array substrate, forming an anode layer and an auxiliary cathode layer on the array substrate, and before the forming a cathode layer on the light emitting layer and the auxiliary cathode layer, the method further comprises:
forming a pixel defining layer on the array substrate, defining a first through hole in the pixel defining layer to face directly the anode layer and to expose the anode layer, and defining a second through hole in the pixel defining layer to face directly the auxiliary cathode layer and to expose at least part of the auxiliary cathode layer; and
the forming a cathode layer on the light emitting layer and the auxiliary cathode layer, comprises:
forming the cathode layer on the light emitting layer, the pixel defining layer, a side wall of the first through hole, a side wall of the second through hole, and the auxiliary cathode layer.
